(19) United States
(12) Patent Application Publication
(10) Pub. No.: US 2025/0149306 A1
(43) Pub. Date: May 8, 2025

(54) WAFER EDGE TILT AND ETCH RATE UNIFORMITY

(71) Applicant: Lam Research Corporation, Fremont, CA (US)

(72) Inventors: Pratik Mankidy, Fremont, CA (US); Jaewon Kim, Pleasanton, CA (US)

(21) Appl. No.: 18/835,982

(22) PCT Filed: Dec. 19, 2022
(86) PCT No.: PCT/US22/53427

§ 371 Date: Aug. 5, 2024

Related U.S. Application Data
(60) Provisional application No. 63/308,383, filed on Feb. 9, 2022.

(51) Int. Cl. H01J 37/32; H01L 21/67; H01L 21/687

(52) U.S. Cl. CPC H01J 37/32642; H01L 21/68735; H01J 2237/3343; H01L 21/67069

(57) ABSTRACT

An edge ring for use in a plasma chamber includes a first pair of edge ring segments with each one of the first pair of edge ring segments having a first thickness and a second pair of edge ring segments with each one of the second pair of edge ring segments having a second thickness. Each of the first pair of edge ring segments is oriented adjacent to each of the second pair of edge ring segments and each of the second pair of edge ring segments is oriented adjacent to each of the first pair of edge ring segments.

### BACKGROUND

### 1. Technical Field

The present embodiments relate to a component used in semiconductor process chamber for providing uniform etch rate, and more particularly, to an edge ring with modified geometry to provide uniform etch rate across a wafer surface.

### 2. Description of the Related Art

A semiconductor wafer is exposed to various fabrication processes to generate electronic devices. The processes that are used to generate electronic devices include deposition processes, etching processes, patterning processes, among others. An etching process is conducted in a plasma chamber. Plasma is generated either remotely or locally in the plasma chamber and ions of the plasma are directed over the surface of the wafer to etch features to define patterns. One or more patterns define an electronic device. Due to high fabrication costs, designers try to maximize yield by increasing density of the electronic devices patterned on the wafer. One way of increasing the density of the electronic devices and hence the yield is by defining high aspect ratio features on the wafer. Another way of increasing the yield is to maximize use of the surface of the wafer by etching high aspect ratio features.

Etching high aspect ratio features on the surface of the wafer and particularly at the edge of the wafer requires optimization of ion flux and ion tilt. Patterns etched on the wafer surface are asymmetric. To assist in optimizing ion flux and ion tilt and for improving edge sheath control at the wafer edge, edge rings are provided adjacent to and surround the wafer. In the various experiments conducted, it is noted that the etch rate performance at the wafer edge varies depending on the orientation of the features in relation to the radius of the wafer (i.e., whether the features are perpendicular or parallel to the radius of the wafer). Currently available edge rings are axisymmetric-being symmetric in geometry along a given axis.

### SUMMARY

Various implementations of the disclosure include apparatuses and systems used for normalizing etch rate across the surface of the wafer. During an etching process, plasma is generated in a plasma chamber using process gases. The generated plasma is directed over a surface of a wafer received in the plasma chamber to define features. The features are part of a pattern that is used to define electronic devices. The features patterned on the wafer are asymmetric and can include slits, vias or trenches.

An edge ring is provided adjacent to and surround a wafer receiving region used to receive the wafer in the plasma chamber. The edge ring is provided to improve ion flux and ion tilt at the wafer edge by extending process region from an edge of the wafer to an outer edge of the edge ring. As noted above, traditional edge rings are axisymmetric—i.e., geometry (e.g., height, angle) of the edge ring is uniform along a given axis. It has been observed from various experiments conducted that the etch rate at the wafer edge varies depending on the orientation of the features defined on the wafer in relation to the wafer radius. For instance, it is observed that the etch rate at the wafer edge is faster in areas of the wafer where the features defined thereon are parallel to the wafer radius. It is further observed that the etch rate at the wafer edge is slower (i.e., normal) in areas where the features on the wafer are perpendicular to the wafer radius. The variation in the etch rate can be attributed to the shape of the plasma sheath at the wafer edge.

To address such variations in the etch rate and to better control the plasma sheath profile at the wafer edge, the edge ring used in the plasma chamber is designed with varying geometry. Specifically, the edge ring is divided into segments and the different segments of the edge ring are defined to extend to different heights. The resulting geometry of the edge ring has a complimentary asymmetry to the asymmetry of the wafer pattern. The heights of the different zones are optimized to ensure that the edge ring with the new geometry is able to “compensate” for the faster etch rate in corresponding areas of the wafer so that the etch rate on the surface of the wafer is uniform.

In one implementation, an edge ring for surrounding a wafer in a plasma chamber, is disclosed. The edge ring includes a first pair of edge ring segments, with each edge ring segment of the first pair having a first thickness. The edge ring also includes a second pair of edge ring segments, with each edge ring segment of the second pair having a second thickness. The first pair of edge ring segments are oriented opposite to each other and the second pair of edge ring segments are oriented opposite to each other. Each one of the first pair of edge ring segments is oriented adjacent to the second pair of edge ring segments. Each one of the second pair of edge ring segments is oriented adjacent to the first pair of edge ring segments.

In another implementation, an edge ring for surrounding a wafer in a plasma chamber, is disclosed. The edge ring includes a first zone, a second zone, a third zone and a fourth zone. The first zone is defined to have a first thickness. The second zone is defined to have a second thickness. The third zone is defined opposite to the first zone and has the first thickness. The fourth zone is defined opposite to the second zone and has the second thickness. Each of the second and fourth zones is defined adjacent to and between the first and the third zones. A transition region is defined between each consecutive pair of the first, the second, the third, and the fourth zones.

Other aspects and advantages will become apparent from the following detailed description, taken in conjunction with the accompanying exemplary drawings.

### BRIEF DESCRIPTION OF THE DRAWINGS

FIG. 1A illustrates a plasma sheath profile at an edge of a wafer received for processing where no edge ring is disposed adjacent to the wafer, in one implementation.

FIG. 1B illustrates the plasma sheath profile at the edge of the wafer received for processing where an edge ring of a first height all around is disposed adjacent to the wafer, in one implementation.

FIG. 1C illustrates the plasma sheath profile at the edge of the wafer received for processing where an edge ring of a second height all around is disposed adjacent to the wafer, in one implementation.

FIG. 2 illustrates a overhead view of an edge ring surrounding a wafer with features defined thereon being oriented in relation to a wafer radius, in accordance with one implementation.

FIG. 3A illustrates a side perspective view of an unwinded edge ring with varying geometry used to surround a wafer receiving region defined in a plasma chamber, in accordance with some implementations.

FIG. 3B illustrates a view of different zones of an unwinded edge ring identifying different features, in accordance with some implementations.

FIG. 3C illustrates a view of different zones of an unwinded edge ring identifying different features, in accordance with an alternate implementation.

FIG. 4A illustrates an overhead view of the edge ring shown in FIG. 3A identifying different zones, in accordance with some implementations.

FIG. 4B illustrates an overhead view of the edge ring of FIG. 4A identifying transition regions defined between different zones, in accordance with some implementations.

FIG. 4C illustrates an overhead view of the edge ring of FIG. 4A identifying transition regions and angle of transition between different zones, in accordance with some implementations.

FIG. 5 illustrates a table showing an etch rate graph for the etch rate at the wafer edge plotted for different heights specified for specific zones of the edge ring, in some implementations.

### DESCRIPTION

In the following description, numerous specific details are set forth in order to provide a thorough understanding of the various embodiments. It will be apparent, however, to one skilled in the art that the described technology may be practiced without some or all of these specific details. In other instances, well known process operations have not been described in detail in order not to unnecessarily obscure the described embodiments.

Implementations of the disclosure provide various details of an edge ring and a system that is used for processing semiconductor substrates (i.e., wafers) that uses the edge ring. It should be appreciated that the present embodiments can be implemented in numerous ways, such as a process, an apparatus, a system, a device, or a method. Several example implementations are described below.

An edge ring is disposed in a plasma chamber adjacent to and surrounds a wafer received in the plasma chamber for processing. The plasma chamber (not shown) includes a top portion and a bottom portion. The top portion can include an upper electrode. The upper electrode can, in one example, be a showerhead. The upper electrode is coupled to one or more gas sources, which provide process gas(es) to a process region defined in the plasma chamber. In some implementations, the upper electrode is coupled to a radio frequency (RF) power source through a matching network to receive RF power to generate plasma in the process region using the process gas(es). The bottom portion of the plasma chamber includes a wafer receiving component, such as a pedestal that is oriented opposite to the upper electrode to define a process region there-between. The pedestal can be an electrostatic chuck (ESC) and include a wafer receiving region defined thereon. The wafer is received on the wafer receiving region in a defined orientation, for processing.

The edge ring is defined to include a plurality of ring segments. The edge ring is used to extend a process region from an edge of a wafer to an outer edge of the edge ring. The edge ring is disposed so that a top surface of the edge ring is co-planar with a top surface of the wafer, when the wafer is received in the plasma chamber. Similar to the wafer being received into the plasma chamber in a defined orientation, the edge ring is also positioned within the plasma chamber in a defined orientation. The defined orientation allows the each ring segment of the edge ring to be adjacent to and align with a corresponding region of the wafer. For example, a first ring segment is disposed adjacent to and aligns with a corresponding first region of the wafer, a second ring segment adjacent to and aligns with a second region, and so on. In the various implementations described herein, the edge ring is designed to have different thickness for different ring segments. The thickness of each ring segment of the edge ring is defined to correspond with orientation of features defined on the corresponding region of the wafer. For example, a ring segment adjacent to a region of the wafer where features are parallel or substantially parallel to the wafer radius is defined to have a first thickness. Similarly, a ring segment adjacent to a region of the wafer where features are perpendicular or substantially perpendicular to the wafer radius is defined to have a second thickness. The variance in the thicknesses in the different ring segments of the edge ring assists in influencing the ion flux and the ion tilt in the respective regions of the wafer edge. Controlling the ion flux and the ion tilt results in controlling plasma sheath profile at the wafer edge so that the etch rate is substantially uniform along the length of the wafer surface including the wafer edge.

The various features of the edge ring will now be discussed with reference to the drawings.

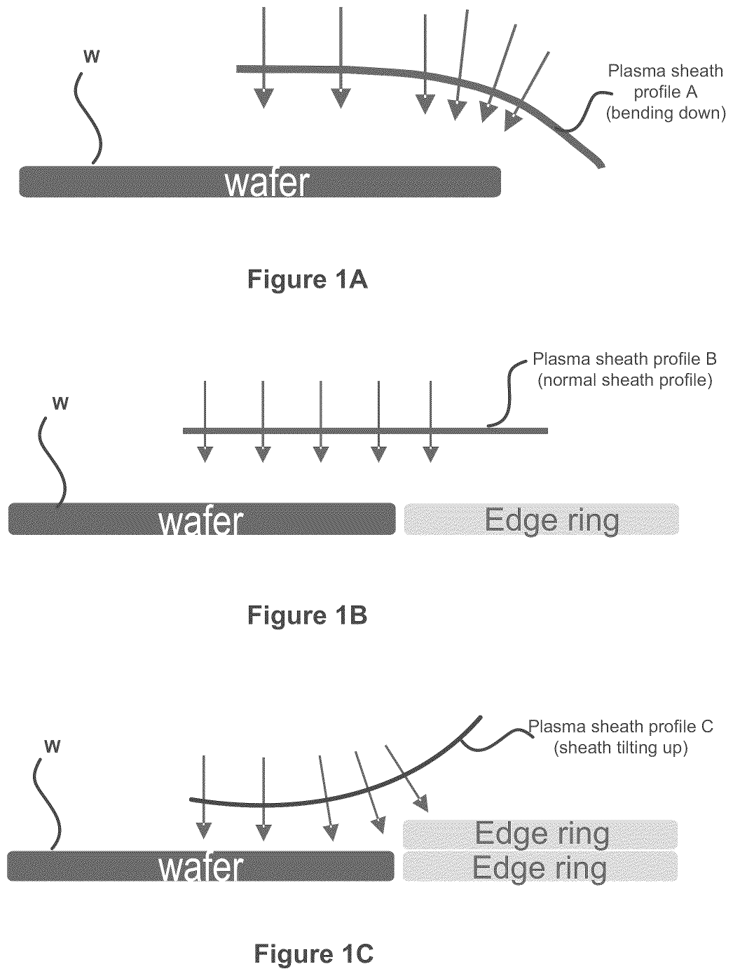

FIGS. 1A-1C illustrate various plasma sheath profiles obtained for different geometry of edge rings. To determine an optimal geometry for the edge ring, it is useful to understand the different plasma sheath profiles formed at the wafer edge in different scenarios and to identify a scenario that provides optimal plasma sheath profile at the wafer edge. FIGS. 1A-1C illustrate plasma sheath profiles (i.e., ion flow profiles) at the wafer edge obtained from various experiments conducted using edge rings of varying thickness, in some implementations. FIG. 1A illustrates plasma sheath profile (i.e., the ion flow—plasma sheath profile A) at the edge of the wafer W when no edge ring is present adjacent to the wafer W. In this illustration, it is noted that the plasma sheath profile A is bent down indicating that the ion flux is focused along the wafer edge. Further experiments were conducted and it was determined that the increase in the ion flux at the wafer edge correlates with the orientation of the features patterned on the wafer surface in relation to the wafer radius. For instance, it was noticed that the etch rate was faster in certain regions where the features are parallel to the wafer radius and nominal in other regions where the features are perpendicular to the wafer radius. The increase in etch rate can be attributed to the increase in the ion flux in those regions along the wafer edge.

FIG. 1B illustrates the plasma sheath profile (plasma sheath profile B) at the edge of the wafer W when a traditional edge ring with flat ring profile (i.e., edge ring having a uniform, nominal thickness along the entirety of the circumference) is used adjacent to the wafer W, in one implementation. The plasma sheath profile B is shown to be a straight line indicating that the ion flux at different regions of the wafer edge is similar to ion flux at the wafer center.

FIG. 1C illustrates the plasma sheath profile (plasma sheath profile C) along the edge of the wafer W when an edge ring with increased thickness (e.g., thickness that is twice the nominal thickness) is used, in one implementation. The plasma sheath profile C is shown to have an upward turn at the wafer edge, indicating that the ion flux is forced upward and away from the wafer edge and toward the edge ring surface.

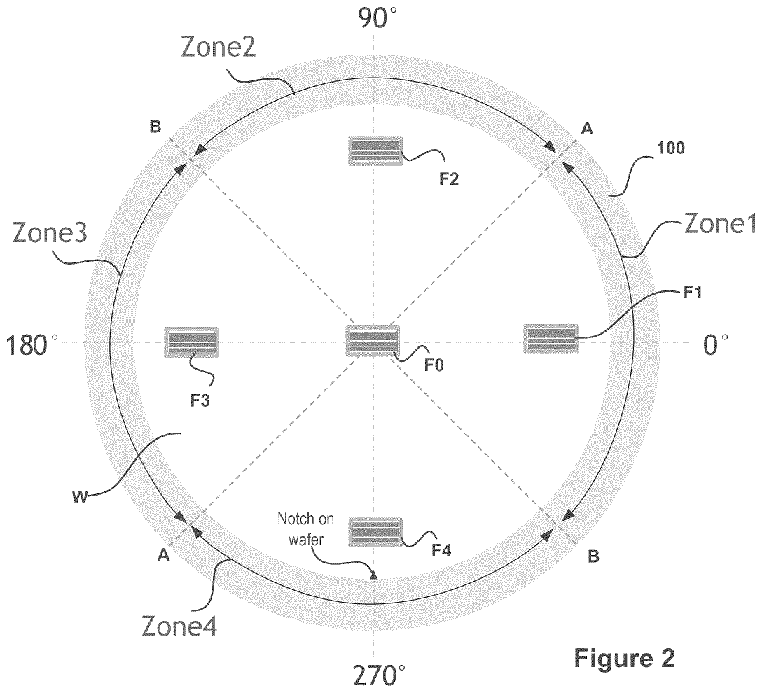

From the various experiments it is noticed that the plasma sheath profile is greatly influenced by the presence of the edge ring and the thickness of the edge ring. Thus, to address the varying etch rates in different regions of the wafer edge, the traditional edge ring is re-designed with varying thickness in different sections in order to influence the etch rates in different portions of the wafer edge. Thus, in accordance with some implementations, the geometry of the edge ring is designed to include a plurality of zones, wherein each zone represents a ring segment. Each of the ring segments (i.e., zones) of the edge ring corresponds with a different region of the wafer. The ring segments are defined to have varying thickness. For example, the thickness of the edge ring is increased in ring segments that correspond with regions of the wafer where the features are parallel to the radius of the wafer. The increase in the thickness in those ring segments assists in diverting the ion flux away from the wafer edge in the corresponding regions. This re-designed geometry is shown to normalize etch rate across the wafer, as will be discussed with reference to FIGS. 2-5.

FIG. 2 illustrates an overhead view of the edge ring 100 received in a plasma chamber and disposed adjacent to and surround a wafer W received for processing, in some implementations. The edge ring surrounding the wafer W is shown to be divided into 4 zones (zones 1-4, also referred to herein as “ring segments”). Each zone is defined to align with a specific region on the adjacent wafer W. The wafer W includes a plurality of features defined thereon, wherein one or more features define an electronic device. FIG. 2 shows the orientation of a sample number of features F1-F5 defined on the wafer W. The number of features shown in FIG. 2 is provided for illustration purposes in order to depict the orientation of some of the features with respect to the radius of the wafer. It should be noted that a wafer W can include more than 5 features, and in some implementations, can have as much as 500 such or similar features defined thereon. Each feature is oriented in relation to the x-axis and the y-axis. For example, as illustrated in FIG. 2, features F1 and F3 are shown to be disposed along the x-axis and parallel to the radius of the wafer defined along the x-axis. Features F2 and F4 are shown to be disposed along the y-axis and are perpendicular to the wafer radius, and feature F0 is disposed in the center of the wafer at the intersection of x-y axes (i.e., perpendicular to the y-axis and parallel to the x-axis). The features patterned on the wafer are asymmetric and may include vias, trenches, slits, etc., between word line cuts, for example. The zones (zones 1-4) on the edge ring illustrated in FIG. 2 are all shown to be equal in size although this might not always be the case.

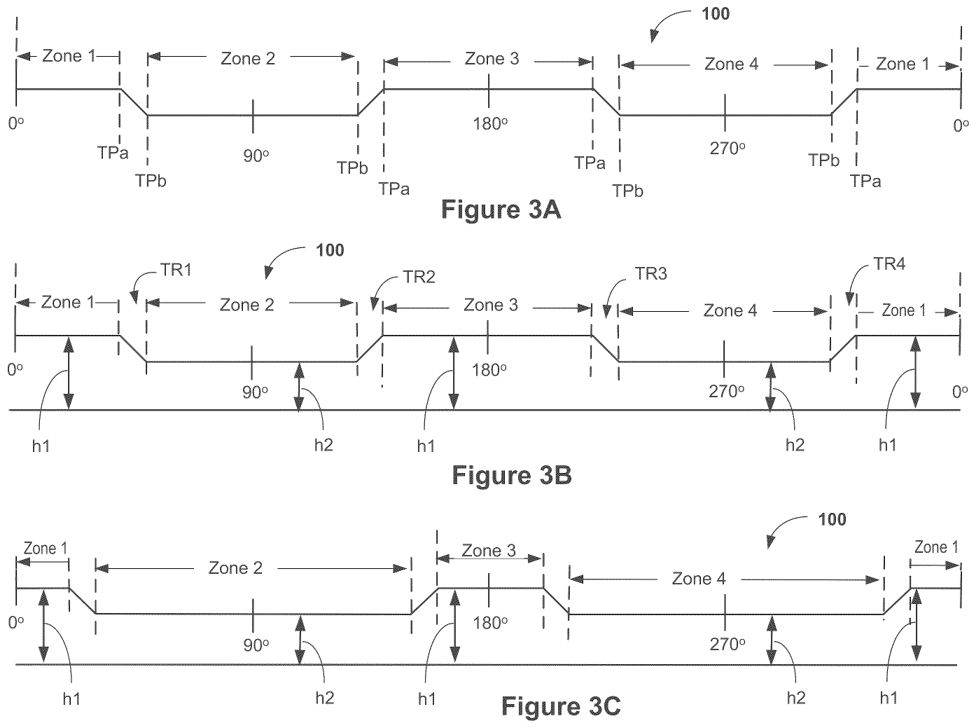

FIGS. 3A-3C show a simplified side cross-sectional view of an edge ring unwinded and represented in a straight line, in some implementations. The straight line illustrations are to show the variation in height in different portions of the edge ring. The edge ring is defined to have a geometry that is different from that of traditional edge rings. Specifically, the edge rings represented in FIGS. 3A-3C are asymmetric, in that the thickness of the edge ring varies and is not uniform along the circumference. The asymmetry of the edge ring is defined to compliment the asymmetry of the features patterned on the wafer W. In contrast, traditional edge rings are defined to be axisymmetric, in that the thickness of the edge ring is uniform along the circumference.

The asymmetric design of the edge ring 100 is accomplished by dividing the edge ring 100 into a plurality of ring segments. Each ring segment is defined to align with a certain region of the wafer where features are formed. Each ring segment of the plurality of ring segment is defined to have a specific thickness, wherein the thickness of any two consecutive ring segments is different. FIG. 3A illustrates the edge ring 100 divided into four ring segments (represented as zones 1-4), in accordance with some implementations. The radians represented in FIG. 3A correspond with the radians of the edge ring identified in FIG. 2. The number and size of the ring segments are defined based on the variation in etch rates observed in different regions along the edge of the wafer received adjacent to the edge ring. Thus, the number of ring segments (i.e., 4 ring segments or zones) illustrated in FIG. 3A is provided as an example and that additional ring segments can also be contemplated, if needed. As noted above, the etch rates in different portions of the wafer edge are observed to vary based on the orientation of the features formed thereon in relation to wafer radius. For instance, the etch rates are observed to be faster in portions of the wafer edge where the features are substantially parallel to the wafer radius. Similarly, the etch rates are observed to be nominal (i.e., regular or normal) in portions of the wafer edge where the features are substantially perpendicular to the wafer radius.

As a result, various ring segments are defined on the edge ring 100 to align with the corresponding regions of the wafer where different etch rates are observed along the wafer edge. A first pair of ring segments (represented as zones 1 and 3) is defined on the edge ring 100 to align with a corresponding first set of regions of the wafer edge where the features patterned are substantially parallel to the radius of the wafer. The first set of regions at the wafer edge is where a faster etch rate has been observed. A second pair of ring segments (represented as zones 2 and 4) is defined on the edge ring to align with a corresponding second set of regions of the wafer edge where the features patterned are substantially perpendicular to the radius of the wafer. The second set of regions at the wafer edge is where a nominal etch rate (i.e., normal or regular and is not faster) has been observed. Zones 1 and 3 representing the first set of ring segments are aligned along a horizontal axis and zones 2 and 4 representing the second set of ring segments are aligned to a vertical axis.

The edge ring with zones 1-4 defined in relation to the radians of the circular edge ring is illustrated in FIG. 3A. It should be noted that zones and ring segments are used interchangeably in this application to refer to certain sections or portions of the edge ring. In the implementations illustrated in FIG. 3A, zones 1-4 are shown to be equal in size. This may not always be the case as the influence of the ion flux may affect a small portion of the wafer region with the remaining major portion experiencing nominal etch rate. Consequently, zones 1-4 can vary in size, as will be discussed with reference to FIG. 3C.

As noted, the variation in the edge etch rates in different regions of the wafer can be attributed to a number of factors, such as direction of gas flow, ion direction, orientation of the devices defined by features patterned on the wafer, etc. The geometry of the edge ring 100 is intentionally changed in certain ring segments that align with regions of the wafer where the edge etch rate is faster in order to “compensate” for the faster etch rate and make the etch rate in those regions similar to the other regions of the wafer. The geometry of the edge ring is changed by increasing the thickness of the edge ring in zones 1 and 3 (i.e., in the first set of ring segments) and maintaining nominal thickness in zones 2 and 4 (i.e., in the second set of ring segments). A transition region is defined at interfaces between increased thickness and nominal thickness. Thus, there is a transition region defined at the interface of each consecutive pair of zones. The transition region extends between a first transition point (TPa) and a second transition point (TPb) for a transition length (not shown). The first transition point TPa is at an increased thickness and the second transition point TPb is at nominal thickness. Further, the transition between the first transition point TPa and the second transition point TPb is smooth and gradual and not straight and abrupt—i.e., the transition points TPa, TPb do not include straight edges but smooth curvatures.

FIG. 3B provides additional details of the ring segments defined in the edge ring 100. As noted above, transition regions are defined between each pair of consecutive ring segments (represented by zones) defined in the edge ring 100, in some implementations. A transition region TRI is defined at a first interface between zones 1 and 2, transition region TR2 is defined at a second interface between zones 2 and 3, and so on. Each transition region transitions between a ring segment of increased thickness and a ring segment of nominal thickness. In some implementations, the increased thickness of the first pair of ring segments represented by zones 1 and 3 is defined to extend for a height ‘h1’ and the nominal thickness of the second pair of ring segments represented by zones 2 and 4 is defined to extend for a height ‘h2’, with height h1 being greater than thickness h2. As noted, the increase in thickness in certain portions (i.e., zones 1 and 3) of the edge ring is to slow down the edge etch rate in those regions of the wafer edge. Since the edge etch rate is influenced by the ion flow direction, the increase in thickness of the edge ring 100 in zones 1 and 3 diverts the ion flow away from the wafer edge and upward toward the edge ring. The resulting geometry of the edge ring, as noted, has the complimentary asymmetry to the asymmetry of the features patterned on the wafer.

In the implementation represented in FIGS. 3A and 3B, each of the zones 1-4 cover an equal portion of the edge ring. Thus, each zone is defined to cover about 90° of the circumference of the edge ring 100. Thus, zones 1 and 3 of the edge ring 100 disposed opposite to each other cover a quarter of the circumference of the edge ring 100. Similarly, zones 2 and 4 of the edge ring disposed opposite to one another each cover a quarter of the circumference of the edge ring 100.

FIG. 3C illustrates an alternate implementation wherein the first pair of edge ring segments represented by zones 1 and 3 has a different size than the second pair of edge ring segments represented by zones 2 and 4. Each zone of the first pair (i.e., zones 1 and 3) is defined by a first size, and each zone of the second pair (i.e., zones 2 and 4) is defined by a second size, wherein the first size is smaller than the second size. In some implementations, zones 1 and 3 are defined to cover one-half the size covered by zones 2 and 4. For example, if each of zones 2 and 4 cover about 120° of the circumference of the edge ring 100, then each of zones 1 and 3 cover about 60° of the circumference of the edge ring 100. In alternate implementations, zones 1 and 3 are defined to cover one-fifth of the size covered by zones 2 and 4. Of course, the sizes of each zone in the first and the second pairs are driven by the areas of the wafer that experience similar etch rate characteristics (i.e., faster etch rate vs. nominal etch rate).

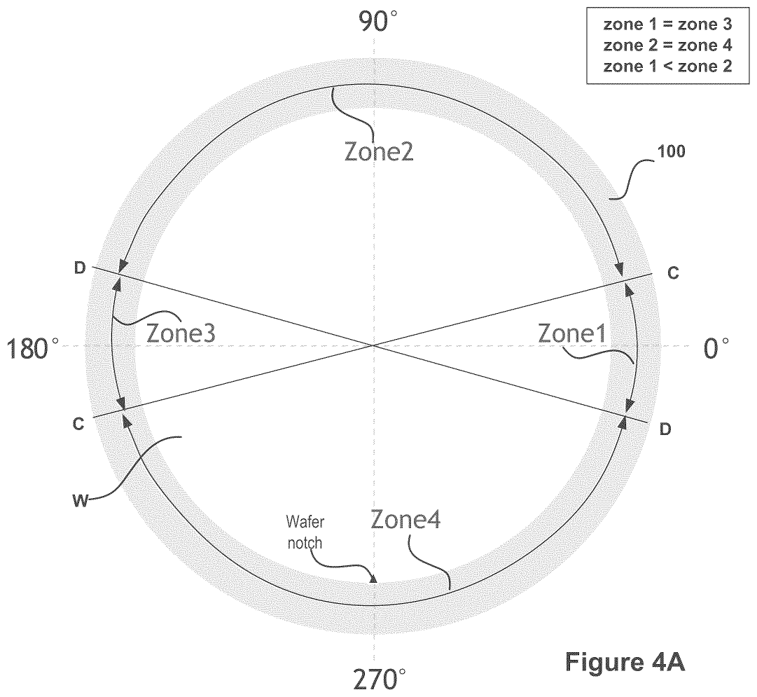

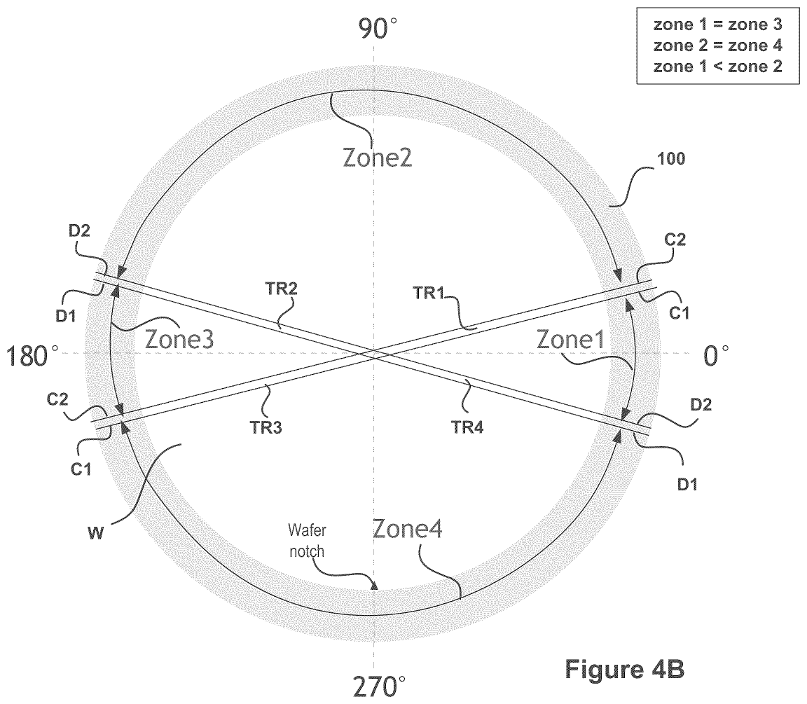

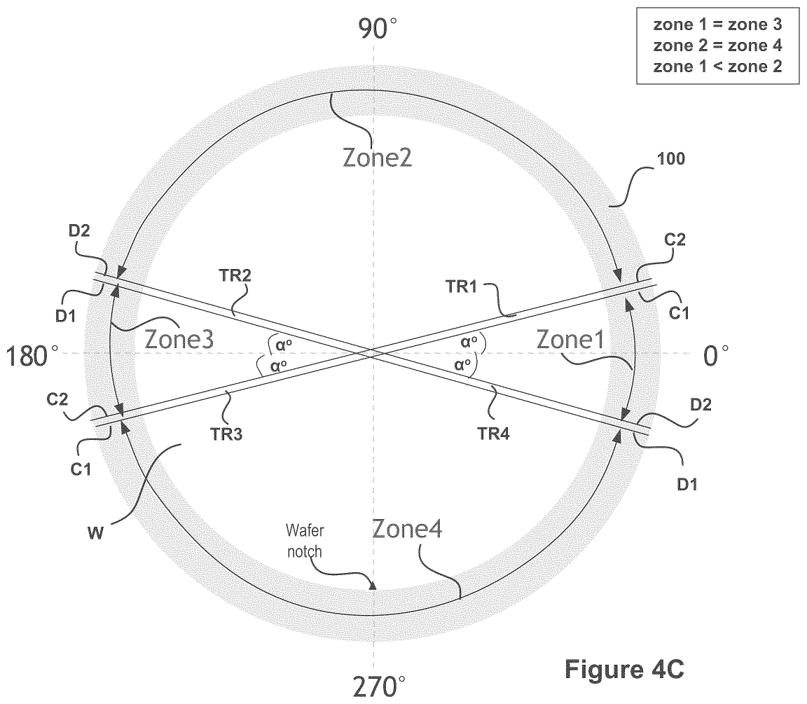

FIG. 4A illustrates a top view of the edge ring 100 with varying geometry used in a plasma chamber, in some implementations. The edge ring is divided into different zones similar to what was shown in FIG. 3C, wherein each zone represents an edge ring segment. The zone dividing lines are represented by lines C-C and D-D. As noted with reference to FIG. 3C, zones 1 and 3 are part of the first pair of ring segments and are oriented opposite to each other and aligned along a horizontal axis. Zones 2 and 4 are part of the second pair of ring segments and are oriented opposite to each other and aligned along a vertical axis. The edge ring is received in the plasma chamber in a defined orientation. In some implementations, the defined orientation is determined in relation to a wafer notch that is used to orient the wafer, when the wafer is received in the plasma chamber. As noted in FIG. 4A, zones 1 and 3 are equal in size and zones 2 and 4 are equal in size. However, zone 1 is smaller than zone 2. Although not shown in FIG. 4A, the thickness of the edge ring in zones 1 and 3 are greater than the thickness of the edge ring in zones 2 and 4.

FIG. 4B illustrates a transition region defined between each pair of consecutive zones, in some implementations. The transition regions are represented between lines C1-C1, C2-C2, D1-D1 and D2-D2. For instance, transition region 1 (TR1) is defined at the interface of zones 1 and 2, TR2 at the interface of zones 2 and 3, TR3 at the interface of zones 3 and 4, and TR4 at the interface of zones 4 and 1. Further, orientation of the zones is shown in relation to the radians of the edge ring 100. Zone 1 is shown oriented symmetrically about 0°, zone 2 oriented symmetrical about 90°, zone 3 oriented symmetrically about 180° and zone 4 oriented symmetrically about 270°.

FIG. 4C illustrates the orientation of the zones in relation to the radians of the circular edge ring, in some implementations. As noted, the zones are separated by a transition region defined at the interface between two consecutive zones. Thus, for the edge ring with four zones defined thereon, there are four transition regions—TR1-TR4. Each of the transition regions extend a transition length between a first transition point (TPa) that is at increased thickness and a second transition point (TPb) that is at nominal thickness. In some implementations, the transition length, in some implementations, is defined to be between about 1 mm and about 3 mm. In some implementations, an angle of inclination between TPa and TPb in the transition region is defined to be between about 30° and about 40°. In other implementations, the angle of inclination between TPa and TPb depends on the increased thickness h1 and nominal thickness h2 and the length of the transition region. In some implementations, zones 1 and 3 of the first pair of ring segments are defined at an angle that is about α° from the horizontal axis (i.e., x-axis). Zones 2 and 4 of the second pair of ring segments are defined to be about (180°-α°). In some implementations, α° is defined to be an acute angle. In some implementations, α° is defined to be about 15°. In alternate implementations, α° is defined to be about 30°. In yet other implementations, α° is defined to be between about 15° and about 30°. In some implementations, the increased thickness h1 defined in zones 1 and 3 is defined to be between about 6.7 mm and about 7.7 mm. In some implementations, the nominal thickness h2 defined in zones 2 and 4 is defined to be between about 6.3 mm and about 7.0 mm. Of course, the various dimensions included herein are provided as examples and should not be considered restrictive or limiting. Further, the use of the term ‘about’ to define the various dimensions can include a variation of +/−15% of the defined range. In some implementations, the edge ring is made of Silicon. In other implementations, the edge ring may include Silicon and other polysilicon materials.

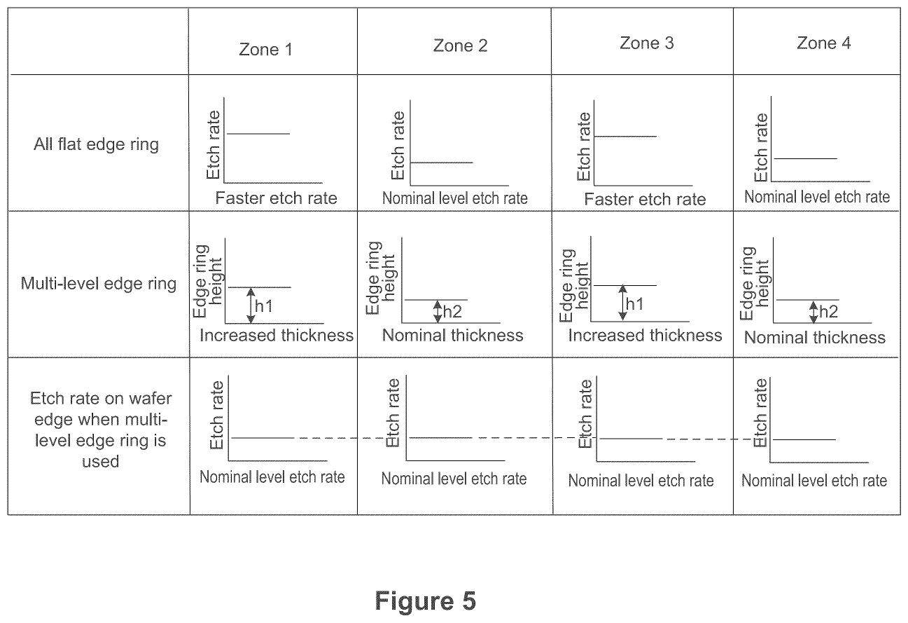

FIG. 5 illustrates a table that briefly summarizes the influence of the edge ring and the thickness of the edge ring on etch rate, in some implementations. As noted, the first row shows etch rate on the wafer edge when a flat edge ring (i.e., axisymmetric edge ring) is used adjacent to and surround a wafer in the plasma chamber. The etch rates vary along different regions of the wafer, with zones 1 and 3 showing faster etch rates and zones 2 and 4 showing nominal etch rates. Row 2 shows a multi-level edge ring that is used to address the varying etch rates observed at the wafer edge so that the etch rate can be uniform across the wafer. As noted above, the edge ring is defined into a plurality of zones with each zone aligning with a certain region of the wafer. The thickness of the edge ring is increased to a height h1 in zones 1 and 3 and maintained at height h2 in zones 2 and 4. Since the edge ring is installed in the plasma chamber at defined orientation, the various zones align with corresponding regions of the wafer so as to influence the etch rate at the corresponding regions of the wafer edge. For instance, zones 1 and 3 are disposed adjacent to and align with regions of the wafer that have faster etch rates while zones 2 and 4 are disposed adjacent to and align with regions of the wafer edge that have nominal etch rates.

Row 3 shows the etch rates experienced at the different regions of the wafer edge when the multi-level edge ring is used in the plasma chamber, in some implementations. With the multi-level edge ring, it is observed that all the regions of the wafer edge that correspond with the corresponding zones of the multi-level edge ring show a nominal etch rate. For instance, the regions on the wafer edge that align with zones 1 and 3 are shown a decrease in etch rate from the faster etch rate shown in row 1 to nominal etch rate shown in row 3.

As noted, the newly designed geometry makes the edge ring asymmetric that compliments the asymmetry of the features patterned on the wafer and is different from the axisymmetric configuration of the conventional edge rings. The height to which certain portions of the edge ring is increased is optimized to reduce the etch rate in those regions of the wafer that showed faster etch rate. The new design of the edge ring results in achieving substantially uniform etch rate across the surface of the wafer including the various portions of the wafer edge by reducing the ion tilt and optimizing ion flux at the wafer edge.

The foregoing description of the various implementations has been provided for purposes of illustration and description. It is not intended to be exhaustive or to limit the described technology. Individual elements or features of a particular implementation are generally not limited to that particular implementation, but, where applicable, are interchangeable and can be used in a selected implementation, even if not specifically shown or described. The same may also be varied in many ways. Such variations are not to be regarded as a departure from the described embodiments, and all such modifications are intended to be included within the scope of the described embodiments.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. An edge ring surrounding a wafer in a plasma chamber, the edge ring comprising:
a first pair of edge ring segments, wherein each one of the first pair of edge ring segments has a first thickness; and
a second pair of edge ring segments, wherein each one of the second pair of edge ring segments has a second thickness, the first pair of edge ring segments oriented opposite to each other and the second pair of edge ring segments oriented opposite to each other,
wherein each one of the first pair of edge ring segments is oriented adjacent to each one of said second pair of edge ring segments, and each one of the second pair of edge ring segments is oriented adjacent to each one of said first pair of edge ring segments.

2. The edge ring of claim 1, wherein a transition region is defined at interfaces between said first thickness and said second thickness.

3. The edge ring of claim 2, wherein said transition region at an interface extends a transition length between a first transition point and a second transition point, said first transition point is defined at said first thickness and said second transition point is defined at said second thickness.

4. The edge ring of claim 3, wherein said transition length extends between about 1 mm and about 3 mm.

5. The edge ring of claim 3, wherein said transition region includes an inclination of between about 30° and about 40° between said first transition point and said second transition point of said interface.

6. The edge ring of claim 1, wherein said first thickness is greater than said second thickness.

7. The edge ring of claim 1, wherein each one of said first pair of edge ring segments having a first size, and each one of said second pair of edge ring segments having a second size, wherein said first size is smaller than said second size.

8. The edge ring of claim 1, wherein said first pair of edge ring segments is aligned along a horizontal axis, and said second pair of edge ring segments is aligned along a vertical axis, wherein each one of said first pair of edge ring segments is disposed to cover an area of the edge ring that is at an acute angle about the horizontal axis.

9. The edge ring of claim 1, wherein said first pair of edge ring segments define a first zone and a third zone, and said second pair of edge ring segments define a second zone and a fourth zone.

10. The edge ring of claim 1, wherein said first thickness is defined to be between about 6.7 mm and about 7.7 mm, and said second thickness is defined to be between about 6.3 mm and about 7.0 mm.

11. A plasma chamber for processing a wafer, comprising:
an upper electrode defined in a top portion for providing process gases into the plasma chamber;
a pedestal defined in a bottom portion and oriented opposite to said upper electrode, the pedestal defining a wafer receiving region thereon;
an edge ring received adjacent to and surround said wafer receiving region, said edge ring includes,
a first pair of edge ring segments, wherein each one of said first pair of edge ring segments has a first thickness; and
a second pair of edge ring segments, wherein each one of said second pair of edge ring segments has a second thickness, the first pair of edge ring segments oriented opposite to each other and the second pair of edge ring segments oriented opposite to each other,
wherein each one of the first pair of edge ring segments is oriented adjacent to each one of said second pair of edge ring segments, and each one of the second pair of edge ring segments is oriented adjacent to each one of said first pair of edge ring segments.

12. The plasma chamber of claim 11, wherein said edge ring is positioned in the plasma chamber such that said first pair of edge ring segments and said second pair of edge ring segments are in defined orientations.

13. The plasma chamber of claim 11, wherein said first thickness is greater than said second thickness,
wherein each of said first pair of edge ring segments is defined by a first size and each of said second pair of edge ring segments is defined by a second size.

14. The plasma chamber of claim 13, wherein said first size is smaller than said second size.

15. The plasma chamber of claim 13, wherein said first size is equal to said second size.

16. An edge ring for surrounding a wafer in a plasma chamber, the edge ring comprising:
a first zone having a first thickness;
a second zone having a second thickness;
a third zone defined opposite to the first zone and having the first thickness;
a fourth zone defined opposite to said second zone and having the second thickness, each of said second and said fourth zones defined adjacent to and between said first and said third zones; and
a transition region defined between each consecutive pair of the first, the second, the third and the fourth zones.

17. The edge ring of claim 16, wherein said first thickness is greater than said second thickness.

18. The edge ring of claim 16, wherein the first and the third zones are aligned along a horizontal axis and said second and said fourth zones are aligned along a vertical axis.

19. The edge ring of claim 16, wherein said transition region extends for a length between a first transition point defined at the first thickness and a second transition point defined at the second thickness.

20. The edge ring of claim 16, wherein each of said first and said third zones having a first size and each of said second and fourth zones having a second size, wherein said first size is less than said second size.
